(19) United States
(12) Patent Application Publication
(10) Pub. No.: US 2025/0040355 A1
(43) Pub. Date: Jan. 30, 2025

(54) DISPLAY PANEL, MANUFACTURING METHOD OF DISPLAY PANEL, AND DISPLAY DEVICE

(71) Applicants: HEFEI VISIONOX TECHNOLOGY CO., LTD., Hefei (CN); VISIONOX TECHNOLOGY INC., Jiangsu (CN)

(72) Inventors: Yongqiang DU, Hefei (CN); Xiaoxi SUN, Hefei (CN); Deqiang ZHANG, Hefei (CN); Xuejing ZHU, Hefei (CN); Bo RAO, Hefei (CN)

(73) Assignees: HEFEI VISIONOX TECHNOLOGY CO., LTD., Hefei (CN); VISIONOX TECHNOLOGY INC., Jiangsu (CN)

(21) Appl. No.: 18/817,630

(22) Filed: Aug. 28, 2024

Related U.S. Application Data
(63) Continuation of application No. PCT/CN2024/077793, filed on Feb. 20, 2024.

(30) Foreign Application Priority Data
Jul. 26, 2023 (CN) 202310938917.5

(51) Int. Cl. H10K 59/122; H10K 59/121

(52) U.S. Cl. CPC H10K 59/122; H10K 59/1216

(57) ABSTRACT

A display panel, a manufacturing method of a display panel, and a display device. The display panel includes a substrate, an array circuit layer, a pixel defining layer, a first capacitor, and multiple sub-pixel units. The array circuit layer includes multiple drive transistors. Each of the multiple sub-pixel units (PX) includes a first electrode. The first capacitor includes a first pole plate and a second pole plate. The pixel defining layer covers the first pole plate, the second pole plate is located on a side of the pixel defining layer facing away from the substrate, an orthographic projection of the first pole plate on the substrate at least partially overlaps with an orthographic projection of the second pole plate on the substrate, and the first pole plate is connected to a gate of a drive transistor.

### CROSS-REFERENCE TO RELATED APPLICATION(S)

This is a continuation of International Patent Application No. PCT/CN2024/077793, filed on Feb. 20, 2024, which claims priority to Chinese Patent Application No. 202310938917.5, filed with the China National Intellectual Property Administration (CNIPA) on Jul. 26, 2023, the disclosures of which are incorporated herein by reference in their entireties.

### TECHNICAL FIELD

Embodiments of the present application relate to the field of display technologies, and for example, to a display panel, a manufacturing method of a display panel, and a display device.

### BACKGROUND

Flat display devices based on technologies such as organic light-emitting diode (OLED) is widely used in various consumer electronic products such as mobile phones, televisions, notebook computers, and desktop computers due to the advantages of high image quality, power saving, thin body, and wide application range, and have become the mainstream of the display devices.

However, the display effect of the OLED display product in the related art still needs to be improved.

### SUMMARY

Embodiments of the present application provide a display panel, a manufacturing method of a display panel, and a display device.

An embodiment of the present application provides a display panel. The display panel includes a substrate, an array circuit layer, a pixel defining layer, multiple sub-pixel units, and a first capacitor. The array circuit layer is located on the substrate and includes multiple drive transistors. The pixel defining layer and the multiple sub-pixel units are located on a side of the array circuit layer facing away from the substrate, and each of the multiple sub-pixel units includes a first electrode. The first capacitor includes a first pole plate and a second pole plate, the first pole plate is disposed in the same layer as the first electrode, the pixel defining layer covers the first pole plate, the second pole plate is located on a side of the pixel defining layer facing away from the substrate, an orthographic projection of the first pole plate on the substrate at least partially overlaps with an orthographic projection of the second pole plate on the substrate, and the first pole plate is connected to a gate of a drive transistor of the multiple drive transistors.

An embodiment of the present application further provides a display panel. The display panel includes a substrate, an array circuit layer, a pixel defining layer, multiple sub-pixel units, a first capacitor and an isolation portion. The array circuit layer is located on the substrate and includes multiple drive transistors. The pixel defining layer and the multiple sub-pixel units are located on a side of the array circuit layer facing away from the substrate, each of the multiple sub-pixel units includes a first electrode, the pixel defining layer includes pixel defining portions and an opening region formed by enclosing the pixel defining portions, and the first electrode is exposed outside the opening region. The first capacitor includes a first pole plate and a second pole plate, an orthographic projection of the first pole plate on the substrate at least partially overlaps with an orthographic projection of the second pole plate on the substrate, and the first pole plate is connected to a gate of a drive transistor of the multiple drive transistors. The isolation portion is located on a side of the substrate, the isolation portion is disposed at least partially around the opening region, an orthographic projection of the isolation portion on the substrate at least partially overlaps with the orthographic projection of the first pole plate on the substrate, and at least part of the isolation portion is also served as the second pole plate.

An embodiment of the present application further provides a manufacturing method of a display panel. The manufacturing method includes that: a substrate is provided; an array circuit layer is formed on the substrate, where the array circuit layer includes multiple drive transistors; a first pole plate and multiple first electrodes respectively included in multiple sub-pixel units are formed on a side of the array circuit layer facing away from the substrate, where the first pole plate is connected to a gate of a drive transistor of the multiple drive transistors; a pixel defining layer is formed on a side of the first pole plate and the multiple first electrodes facing away from the substrate, where the pixel defining layer covers the first pole plate; and a second pole plate is formed on a side of the pixel defining layer facing away from the substrate, where an orthographic projection of the first pole plate on the substrate at least partially overlaps with an orthographic projection of the second pole plate on the substrate, and the first pole plate and the second pole plate are two pole plates of a first capacitor.

An embodiment of the present application further provides a display device, and the display device includes the display panel in any of the embodiments of the present application.

### BRIEF DESCRIPTION OF DRAWINGS

FIG. 1 is a top view of a display panel according to an embodiment of the present application;

FIG. 2 is a sectional view of the display panel shown in FIG. 1 taken along a sectional line BB′;

FIG. 3 is a schematic structural diagram of a pixel circuit according to an embodiment of the present application;

FIG. 4 is another sectional view of the display panel shown in FIG. 1 taken along a section line BB′;

FIG. 5 is an enlarged view of an M region in a display panel shown in FIG. 1;

FIG. 6 is another schematic structural diagram of a pixel circuit according to an embodiment of the present application;

FIG. 7 is a flowchart of a manufacturing method of a display panel according to an embodiment of the present application;

FIG. 8 is a schematic structural diagram of a display panel formed in part of steps in the manufacturing method of the display panel according to an embodiment of the present application;

FIG. 9 is a schematic structural diagram of a display panel formed in another part of steps in the manufacturing method of the display panel according to an embodiment of the present application;

FIG. 10 is a schematic structural diagram of a display panel formed in another part of steps in the manufacturing method of the display panel according to an embodiment of the present application; and

FIG. 11 is a schematic structural diagram of a display panel formed in another part of steps in the manufacturing method of the display panel according to an embodiment of the present application.

### DETAILED DESCRIPTION

It should be noted that the terms “first”, “second” and the like in the Description and claims of the present application, and in the foregoing drawings, are used for distinguishing between similar objects and not necessarily for describing a particular order or sequential order. It should be understood that the data so used are interchangeable as appropriate so that embodiments of the present application described herein can be implemented in an order other than those illustrated or described herein. Moreover, the terms “include” and “have” as well as any variations thereof, are intended to cover a non-exclusive inclusion, for example, the terms “include” and “have” as well as any variations thereof include a process, a method, a system, a product, or an apparatus of a series of steps or units shown in the embodiments of the present application, and also include other processes, methods, systems, products or apparatuses of a series of steps or units not expressly listed or other steps or units inherent to such process, method, system, product, or apparatus.

In a display panel with a high pixels per inch (PPI), due to the limited area of the single sub-pixel, a storage capacitor in a pixel circuit is difficult to be enlarged, which affects the stability of a gate voltage of a drive transistor in the pixel circuit, causes display abnormalities such as flickering, bright spots of the black picture and the like in the display panel, and constrains the improvement of the display effect.

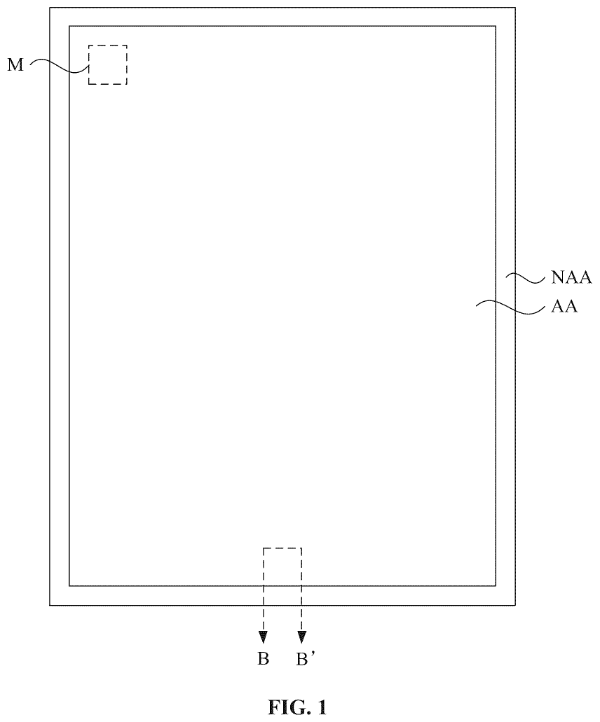

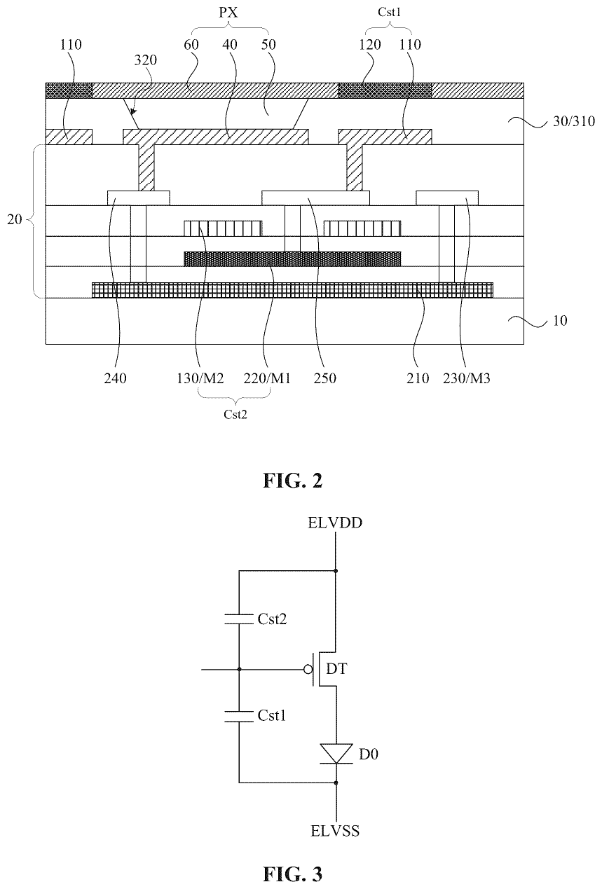

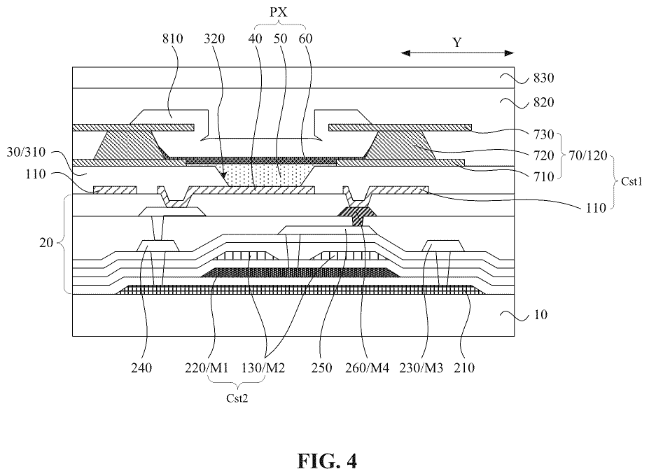

An embodiment of the present application provides a display panel. FIG. 1 is a top view of a display panel according to an embodiment of the present application; FIG. 2 is a sectional view of the display panel shown in FIG. 1 taken along a sectional line BB′; and FIG. 3 is a schematic structural diagram of a pixel circuit according to an embodiment of the present application. With reference to FIG. 1 to FIG. 3, the display panel includes a substrate 10, an array circuit layer 20, a pixel defining layer 30, a first capacitor Cst1, and multiple sub-pixel units PX. In this embodiment of the present application, the first capacitor is formed on the premise of not additionally increasing the number of film layers in the display panel nor corresponding mask plates of the display panel, and the first capacitor is used as the storage capacitor in the pixel circuit, so that a capacitance value of the storage capacitor can be increased, avoiding constraining the capacitance value of the storage capacitor due to the high PPI design, improving the stability of the gate voltage of the drive transistor, and improving the display effect of the display panel.

The array circuit layer 20 is located on the substrate 10, the array circuit layer 20 includes multiple pixel circuits, and each of the multiple pixel circuits includes a drive transistor DT. The pixel defining layer 30 and the sub-pixel units PX are located on a side of the array circuit layer 20 facing away from the substrate 10, and each of the sub-pixel units PX includes a first electrode 40. The first capacitor Cst1 includes a first pole plate 110 and a second pole plate 120. The first pole plate 110 is disposed in the same layer as the first electrode 40. The pixel defining layer 30 covers the first pole plate 110. The second pole plate 120 is located on a side of the pixel defining layer 30 facing away from the substrate 10. An orthographic projection of the first pole plate 110 on the substrate 10 at least partially overlaps with an orthographic projection of the second pole plate 120 on the substrate 10. The first pole plate 110 is connected to a gate 220 of the drive transistor DT.

The substrate 10 may protect and support the display panel. The substrate 10 may be a flexible substrate, which may be made of a material of a polyimide (PI), a polyethylene naphthalate (PEN), a polyethylene terephthalate (PET), and the like, or a mixed material of the above-described multiple materials. The substrate 10 may also be a hard substrate, which is made of a material such as a glass.

The display panel has a display region AA and a non-display region NAA. The multiple sub-pixel units PX are disposed in the display region AA, and the sub-pixel units PX are located in a region defined by the pixel defining layer 30. Each sub-pixel unit PX includes the first electrode 40, and the pixel circuit is electrically connected to the first electrode 40 of a corresponding sub-pixel unit PX, to drive the corresponding sub-pixel unit PX to emit light. In an example, the sub-pixel unit PX includes a light emitting device D0. The light emitting device D0 may be an organic light-emitting diode (OLED) or a micro light emitting diode (Micro-LED), and the like. The first electrode 40 is an electrode, such as an anode, of the light emitting device D0. The drive transistor DT and the light emitting device D0 are connected between a first power supply line ELVDD and a second power supply line ELVSS. The drive transistor DT can generate the drive current according to the gate voltage of the drive transistor DT, to drive the light emitting device D0 to emit light, so that the display panel can display.

Since an overlapping region exists between the orthographic projection of the first pole plate 110 on the substrate 10 and the orthographic projection of the second pole plate 120 on the substrate 10, the pixel defining layer 30 covers the first pole plate 110, the second pole plate 120 is located on the side of the pixel defining layer 30 facing away from the substrate 10, so that the first pole plate 110 may be insulated from the second pole plate 120 through the pixel defining layer 30, and the first pole plate 110 and the second pole plate 120 can form the first capacitor Cst1. The first pole plate 110 of the first capacitor Cst1 is connected to the gate 220 of the drive transistor DT, so that the first capacitor Cst1 may be used as the storage capacitor of the pixel circuit to store the gate voltage of the drive transistor DT through the first capacitor Cst1.

In the technical solutions of the embodiments of the present application, the gate voltage of the drive transistor DT is stored by the first capacitor Cst1, and in the first capacitor Cst1, the first pole plate 110 is disposed in the same layer as the first electrode 40, the second pole plate 120 is disposed on the side of the pixel defining layer 30 facing away from the substrate 10, and the first pole plate 110 is insulated from the second pole plate 120 through the pixel defining layer 30. Since a dielectric constant of a material of the pixel defining layer 30 is relatively large and a thickness of the pixel defining layer 30 is generally relatively thin, by that the pixel defining layer 30 is used as a capacitor dielectric layer between the first pole plate 110 and the second pole plate 120, a capacitance value of the first capacitor Cst1 is increased, improving the stability of the gate voltage of the drive transistor DT, and improving the display effect of the display panel.

In conclusion, in the technical solutions of the embodiments of the present application, the first capacitor is formed on the premise of not additionally increasing the display panel film layer and the corresponding mask plate, and the first capacitor is used as the storage capacitor in the pixel circuit, which is conductive to increasing the capacitance value of the storage capacitor, avoiding the high pixels per inch (PPI) design from constraining the capacitance value of the storage capacitor, improving the stability of the gate voltage of the drive transistor by means of increasing the capacitance value of the storage capacitor, and thus improving the display effect of the display panel.

The first capacitor Cst1 may be set in various ways, and several of them will be described below.

With reference to FIG. 1 to FIG. 3, in an implementation manner, the sub-pixel unit PX further includes a second electrode 60, the second electrode 60 is located on the side of the pixel defining layer 30 facing away from the substrate 10, and a material of the second pole plate 120 is different from a material of the second electrode 60. The second electrode 60 may be a cathode of the light emitting device D0. Both the second pole plate 120 and the second electrode 60 are located on the side of the pixel defining layer 30 facing away from the substrate 10. Both the second pole plate 120 and the second electrode 60 may be made of a conductive material, and a light transmittance of the second electrode 60 is greater than a light transmittance of the second pole plate 120. In one or more embodiments, the second pole plate 120 may be disposed on a different layer from the second electrode 60, that is, the second pole plate 120 and the second electrode 60 are located in different layers. Although both the second pole plate 120 and the second electrode 60 are located on the side of the pixel defining layer 30 facing away from the substrate 10, the second pole plate 120 and the second electrode 60 are formed in the manufacturing processes of different film layers. For example, the second pole plate 120 may be firstly formed on the side of the pixel defining layer 30 facing away from the substrate 10, and then the second electrode 60 is formed on the side of the second pole plate 120 facing away from the substrate 10. The material of the second pole plate 120 is set to be different from the material of the second electrode 60, and/or the second pole plate 120 and the second electrode 60 are set to be located at different layers, so that the second pole plate 120 and the second electrode 60 are formed as different separated structures instead of being formed as an integrated structure. The second pole plate 120 and the second electrode 60 are disposed in a space at the side of the pixel defining layer 30 facing away from the substrate 10, separately, to avoid increasing the thickness of the display panel on the basis of implementing the foregoing effects.

In one or more embodiments, the pixel defining layer 30 includes pixel defining portions 310 and an opening region 320 formed by enclosing the pixel defining portions 310. The first electrode 40 is exposed outside the opening region 320. The pixel defining portion 310 covers the first pole plate 110, and the second pole plate 120 is located on a side of the pixel defining portion 310 facing away from the substrate 10. The pixel defining portion 310 spaces the first pole plate 110 apart from the second pole plate 120, where the first pole plate 110 is insulated from the second pole plate 120. The display panel further includes a light emitting layer 50, where the light emitting layer 50 is disposed in the opening region 320 and is located on a side of the first electrode 40 facing away from the substrate 10. The second electrode 60 is located on a side of the light emitting layer 50 facing away from the substrate 10, the second electrode 60 receives a power supply voltage, and the second pole plate 120 is in contact with the second electrode 60 to receive the power supply voltage. The power supply voltage may be a fixed voltage or a voltage whose voltage value is variable. For example, in the same display period, the power supply voltage remains unchanged, and in different display periods, values of the power supply voltage may be different.

The pixel defining portion 310 is made of an insulating material having a relatively large dielectric constant and a relatively thin thickness. The pixel defining portion 310 is used as the capacitor dielectric layer between the first pole plate 110 and the second pole plate 120, which is conductive to increasing the capacitance value of the first capacitor Cst1, improving the stability of the gate voltage of the drive transistor DT, and improving the display effect of the display panel. The second electrode 60 is partly located on the side of the light emitting layer 50 facing away from the substrate 10 and is partly located on the side of the pixel defining portion 310 facing away from the substrate 10, and the second pole plate 120 is in contact with the second electrode 60 to implement the electrical connection. The second electrode 60 as the cathode of the light emitting device D0 is connected to the second power supply line ELVSS, and the second power supply line ELVSS inputs the power supply voltage, that is, the second power supply line ELVSS transmits the power supply voltage to the second electrode 60, so that both the second electrode 60 and the second pole plate 120 receive the power supply voltage. The second pole plate 120 is disposed to be in contact with the second electrode 60 to receive the power supply voltage, so that the potential of the second pole plate 120 in the same display period is fixed, the gate voltage of the drive transistor DT is stored through the first capacitor Cst1. In this way, the power supply voltage may be also served as the fixed voltage that needs to be input to the second pole plate 120 without additionally providing the fixed voltage to the second pole plate 120, which is conductive to reducing the number of signal terminals and signal lines for transmitting voltage signals in the display panel, simplifying the structure of the display panel.

FIG. 4 is another sectional view of the display panel shown in FIG. 1 taken along a section line BB′. With reference to FIG. 3 and FIG. 4, in another implementation manner, the display panel includes a substrate 10, an array circuit layer 20, a pixel defining layer 30, a first capacitor Cst1, an isolation portion 70, and multiple sub-pixel units PX. The array circuit layer 20 is located on the substrate 10, the array circuit layer 20 includes multiple pixel circuits, and each of the multiple pixel circuits includes a drive transistor DT. Each of the multiple sub-pixel units PX includes a first electrode 40. The pixel defining layer 30 and the first electrode 40 are located on a side of the array circuit layer 20 facing away from the substrate 10. The pixel defining layer 30 includes pixel defining portions 310 and an opening region 320 formed by enclosing the pixel defining portions 310. The first electrode 40 is exposed outside the opening region 320. The first capacitor Cst1 includes a first pole plate 110 and a second pole plate 120, an orthographic projection of the first pole plate 110 on the substrate 10 at least partially overlaps with an orthographic projection of the second pole plate 120 on the substrate 10, and the first pole plate 110 is connected to a gate 220 of the drive transistor DT. The isolation portion 70 is located on the substrate 10. An orthographic projection of the isolation portion 70 on the substrate 10 at least partially overlaps with the orthographic projection of the first pole plate 110 on the substrate 10, and at least part of the isolation portion 70 is also served as the second pole plate 120.

The isolation portion 70 is made of a conductive material, for example, the isolation portion 70 includes a metal material. The isolation portion 70 may be disposed on a side of the pixel defining layer 30 facing away from the substrate 10, for example, the isolation portion 70 is disposed at least partially around the opening region 320. In one or more embodiments, the first pole plate 110 is disposed in the same layer as the first electrode 40, the pixel defining layer 30 covers the first pole plate 110, and the isolation portion 70 is located on the side of the pixel defining layer 30 facing away from the substrate 10, so that the first pole plate 110 is insulated from the isolation portion 70 through the pixel defining layer 30. Each sub-pixel unit PX may include a first electrode 40, a light emitting layer 50, and a second electrode 60. The isolation portion 70 is located between adjacent sub-pixel units PX, to isolate the adjacent sub-pixel units PX. Since the first pole plate 110 is insulated from the isolation portion 70 through the pixel defining layer 30, the orthographic projection of the isolation portion 70 on the substrate 10 overlaps with the orthographic projection of the first pole plate 110 on the substrate 10. The isolation portion 70 is also served as the second pole plate 120, and the first pole plate 110 and the isolation portion 70 may be used to form the first capacitor Cst1, and the first capacitor Cst1 may be used as the storage capacitor, so that on the basis of implementing the foregoing effects, the existing isolation portion 70 in the display panel is also served as the second pole plate 120 without additionally providing the second pole plate 120, simplifying the manufacturing process of the display panel.

In one or more embodiments, the isolation portion 70 also serving as the second pole plate 120 receives the power supply voltage, so that the potential of the second pole plate 120 in the same display period is fixed and the gate voltage of the drive transistor DT is stored through the first capacitor Cst1. In this way, the power supply voltage may be also served as the fixed voltage that needs to be input to the second pole plate 120 without additionally providing the fixed voltage to the second pole plate 120, which is conductive to reducing the number of signal terminals and signal lines for transmitting voltage signals in the display panel, simplifying the structure of the display panel.

In one or more embodiments, the isolation portion 70 is located on a side of the pixel defining portion 310 facing away from the substrate 10, the pixel defining portion 310 covers the first pole plate 110, and the pixel defining portion 310 insulates the first pole plate 110 from the isolation portion 70. The first electrode 40, the light emitting layer 50, and the second electrode 60 that are located in the same opening region 320 are from the same sub-pixel unit PX, and a gap exists between the light emitting layer 50 of the sub-pixel unit PX and a side surface of the isolation portion 70, that is, the light emitting layers 50 of the multiple sub-pixel units PX are spaced apart at the side surface of the isolation portion 70. The light emitting layers 50 of the adjacent sub-pixel units PX are isolated by the isolation portion 70, and the second electrode 60 is lapped to the isolation portion 70.

In conclusion, according to the technical solutions of the embodiments of the present application, the first pole plate 110 is connected to the gate of the drive transistor DT, so that the first pole plate 110 is disposed on a same layer as the first electrode 40. The first pole plate 110 is used as one pole plate of the first capacitor Cst1, the isolation portion 70 is used as another pole plate of the first capacitor Cst1, and the pixel defining portion 310 is used as a capacitor dielectric layer between the two pole plates. On the basis of implementing the foregoing effects, the isolation portion 70 is also served as the second pole plate 120, and the second electrode 60 is disposed to be lapped to the adjacent isolation portion 70, so that the isolation portion 70 receives the power supply voltage. On one hand, the power supply voltage may also be served as the fixed voltage that needs to be input to the second pole plate 120, so that the first capacitor Cst1 can store the gate voltage of the drive transistor DT without additionally providing the fixed voltage to the isolation portion 70, which is conductive to reducing the number of signal terminals and signal lines used for transmitting voltage signals in the display panel, simplifying the structure of the display panel. On the other hand, both the second electrode 60 and the isolation portion 70 receive the power supply voltage, so that the overall resistance of the second electrode 60 and the isolation portion 70 is relatively small, to alleviate the influence of the voltage drop of the power supply voltage on the second electrode 60 on the magnitude of the power supply voltage, reducing the difference in the magnitude of the power supply voltage input to different regions of the display panel, avoiding the abrupt change of the power supply voltage from affecting the amount of charge stored in the first capacitor Cst1, and facilitating the stability of the gate voltage of the drive transistor DT.

Still referring to FIG. 4, in one or more embodiments, the isolation portion 70 includes a first sub-isolation portion 710, a second sub-isolation portion 720, and a third sub-isolation portion 730. The first sub-isolation portion 710, the second sub-isolation portion 72 and the third sub-isolation portion 730 are disposed in a stacked manner and are disposed on the side of the pixel defining portion 310 facing away from the substrate 10 in sequence. Each of the first sub-isolation portion 710, the second sub-isolation portion 720 and the third sub-isolation portion 730 is a conductive isolation portion, or each of at least two adjacent of the first sub-isolation portion 710, the second sub-isolation portion 720 and the third sub-isolation portion 730 is a conductive isolation portion. An orthographic projection of the conductive isolation portion on the substrate 10 at least partially overlaps with the orthographic projection of the first pole plate 110 on the substrate 10, and at least part of the conductive isolation portion is also served as the second pole plate 120 and is configured to receive the power supply voltage.

Each of the first sub-isolation portion 710, the second sub-isolation portion 720 and the third sub-isolation portion 730 may be a conductive isolation portion, or the first sub-isolation portion 710 and the second sub-isolation portion 720 may be conductive isolation portions, or the second sub-isolation portion 720 and the third sub-isolation portion 730 may be conductive isolation portions, or the first sub-isolation portion 710, the second sub-isolation portion 720 and the third sub-isolation portion 730 are all conductive isolation portions. The conductive isolation portion is made of a conductive material (such as, a metal material). The at least part of the conductive isolation portion is also served as the second pole plate 120 and receives the power supply voltage, so that on the basis of implementing the foregoing effects, the conductive isolation portion is also served as the second pole plate 120 without additionally proving the second pole plate 120, which facilitates simplifying the manufacturing process of the display panel.

In one or more embodiments, in a direction perpendicular to the substrate 10, a cross-section of each of the first sub-isolation portion 710 and the third sub-isolation portion 730 is rectangular, and a cross-section of the second sub-isolation portion 720 is rectangular or trapezoid. When the cross-section of the second sub-isolation portion 720 is trapezoid, a base of the trapezoid is adjacent to the first sub-isolation portion 710, and a top of the trapezoid is adjacent to the third sub-isolation portion 720. An orthographic projection of the third sub-isolation portion 730 on the substrate 10 covers an orthographic projection of the first sub-isolation portion 710 on the substrate 10, and the orthographic projection of the third sub-isolation portion 730 on the substrate 10 covers an orthographic projection of the second sub-isolation portion 720 on the substrate 10.

In an example, a length of the third sub-isolation portion 730 may be set to be greater than or equal to a length of the first sub-isolation portion 710, and the length of the third sub-isolation portion 730 is set to be greater than or equal to a length of the second sub-isolation portion 720. The length of the second sub-isolation portion 720 may be a length of the second sub-isolation portion 720 facing to the first sub-isolation portion 710 or facing to the third sub-isolation portion 730. The length of each sub-isolation portion is a size of an edge of the each sub-isolation portion parallel to the first direction Y, and the first direction Y is parallel to a side surface of the substrate 10 facing the isolation portion 70. In this way, the orthographic projection of the third sub-isolation portion 730 on the substrate 10 may cover the orthographic projection of the first sub-isolation portions 710 on the substrate 10, and the orthographic projection of the third sub-isolation portion 730 on the substrate 10 covers the orthographic projection of the second sub-isolation portion 720 on the substrate 10, that is, in the first direction Y, two side edges of the first sub-isolation portion 710 are retracted relative to two side edges of the third sub-isolation portion 730, and two side edges of the second sub-isolation portion 720 are retracted relative to two side edges of the third sub-isolation portion 730. In this way, when the second electrodes 60 are formed, the second electrodes 60 of adjacent sub-pixel units PX are enabled to be spaced apart by the first sub-isolation portion 710 of the isolation portion 70, so that the second electrode 60 is formed between adjacent isolation portions 70, and the second electrode 60 may be lapped to the first sub-isolation portion 70, or the second electrode 60 is lapped to both the first sub-isolation portion 710 and the second sub-isolation portion 720. In a case where the first sub-isolation portion 710 is a conductive isolation portion, the first sub-isolation portion 710 is enabled to receive the power supply voltage through the second electrode 60; or, in a case where the first sub-isolation portion 710 and the second sub-isolation portion 720 are conductive isolation portions, the first sub-isolation portion 710 and the second sub-isolation portion 720 are enabled to receive the power supply voltage through the second electrode 60.

Still referring to FIG. 4, the pixel defining portion 310 includes an inorganic insulating layer material. In one or more embodiments, the pixel defining portion 310 includes at least one of a silicon oxide layer or a silicon nitride layer. For example, the pixel defining portion 310 may be made of a silicon oxide material, that is, the pixel defining portion 310 is made of a silicon oxide layer; or, the pixel defining portion 310 may be made of a silicon nitride material, that is, the pixel defining portion 310 is a silicon nitride layer; or, the pixel defining portion 310 may further include at least one silicon oxide layer and at least one silicon nitride layer that are disposed in a stacked manner. The pixel defining portion 310 is formed by using an inorganic insulating layer material such as silicon oxide and/or silicon nitride, which is conductive to increasing the dielectric constant of the pixel defining portion 310, and increasing the capacitance value of the first capacitor Cst1.

In one or more embodiments, a total thickness of the pixel defining portion 310 ranges from 100 nm to 1000 nm, for example, the total thickness of the pixel defining portion 310 may be 500 nm. In this way, the thickness of the pixel defining portion 310 is relatively thin, further increasing the capacitance value of the first capacitor Cst1.

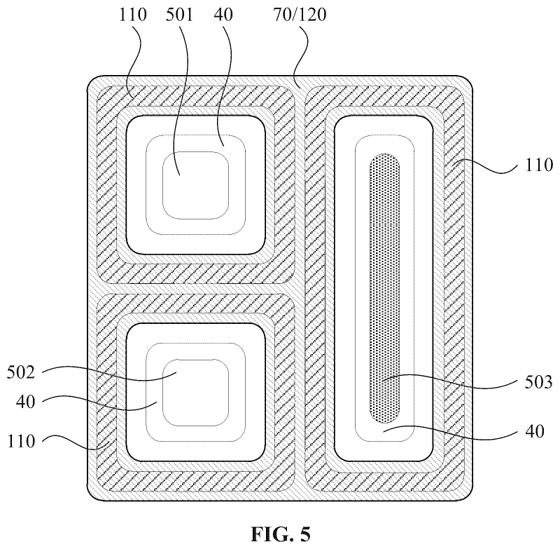

FIG. 5 is an enlarged view of an M region in a display panel shown in FIG. 1, and only part of film layers of the display panel are shown. With reference to FIG. 4 and FIG. 5, in one or more embodiments, the first pole plate 110 is insulated from the first electrode 40, and part of the first pole plate 110 is located between adjacent first electrodes 40. The first pole plate 110 is disposed by using a region between the adjacent first electrodes 40, so that on the basis of implementing the foregoing effects, the space utilization of the display panel can be improved.

In one or more embodiments, the first pole plate 110 is disposed around the first electrode 40, and the first pole plate 110 may form a ring-shaped structure around the periphery of the first electrode 40. The second pole plate 120 is disposed around the opening region 320 of the pixel defining layer 30, and an overlapping region between the orthographic projection of the first pole plate 110 on the substrate 10 and the orthographic projection of the second pole plate 120 on the substrate 10 surrounds the opening region 320. In this way, the space utilization of the display panel can be further improved, and moreover, areas of the first pole plate 110 and the second pole plate 120 may be increased, to increase the vertical overlapping area of the first pole plate 110 and the second pole plate 120, increasing the capacitance value of the first capacitor Cst1, further improving the stability of the gate voltage of the drive transistor DT, and further improving the display effect.

With reference to FIG. 3 to FIG. 5, in one or more embodiments, the first pole plate 110 of the first capacitor Cst1 connected to the same pixel circuit is disposed around the first electrode 40 of the sub-pixel unit PX driven by the pixel circuit. In an example, the sub-pixel unit PX includes a sub-pixel unit having a first-color light emitting layer 501, a sub-pixel unit having a second-color light emitting layer 502, and a sub-pixel unit having a third-color light emitting layer 503. The first-color, the second-color, and the third-color are different colors. For example, the first-color is red, the second-color is green, and the third-color is blue. The first pole plate 110 of the first capacitor Cst1 connected to each pixel circuit is disposed around the first electrode 40 of the sub-pixel unit PX driven by the pixel circuit, so that the first pole plate 110 is connected to the drive transistor DT of a corresponding pixel circuit, simplifying the manufacturing process of the display panel.

With reference to FIG. 2 and FIG. 3, the display panel further includes a connection electrode 250, and the connection electrode 250 is disposed in the same layer as a source 230 of the drive transistor DT or a drain 240 of the drive transistor DT. The connection electrode 250 is electrically connected to the gate 220 of the drive transistor DT and the first pole plate 110, separately. The first pole plate 110 is connected to the gate 220 of the drive transistor DT through the connection electrode 250. An orthographic projection of the connection electrode 250 on the substrate 10 overlaps with an orthographic projection of the gate 220 of the drive transistor DT on the substrate 10.

In an example, the transistor shown in FIG. 3 may be the drive transistor DT. Since the orthographic projection of the first pole plate 110 on the substrate 10 overlaps with the orthographic projection of the second pole plate 120 on the substrate 10, the connection electrode 250 is electrically connected to the gate 220 of the drive transistor DT and the first pole plate 110, separately, and the orthographic projection of the connection electrode 250 on the substrate 10 overlaps with the orthographic projection of the gate 220 of the drive transistor DT on the substrate 10, the first capacitor Cst1 may be equivalent to a capacitor formed by the gate 220 of the drive transistor DT and the second pole plate 120. As the second pole plate 120 receives the fixed voltage, so that the gate voltage of the drive transistor DT is stored through the first capacitor Cst1, which is equivalent to an increase in a vertical overlapping area between the gate 220 of the drive transistor DT and the second pole plate 120, being conductive to increasing the capacitance value of the first capacitor Cst1.

FIG. 2 shows a case in which the connection electrode 250 is directly electrically connected to the first pole plate 110. With reference to FIG. 3 and FIG. 4, in another implementation manner, the display panel further includes a connection portion 260, the connection portion 260 is connected between the first pole plate 110 and the connection electrode 250, and the connection portion 260 is located in a metal layer between the first pole plate 110 and the connection electrode 250, to electrically connect the first pole plate 110 and the connection electrode 250.

With reference to FIG. 3 and FIG. 4, the array circuit layer 20 includes multiple metal layers. An insulating layer is disposed between two adjacent metal layers of the multiple metal layers. The multiple metal layers include a first metal layer M1 and a second metal layer M2. The gate 220 of the drive transistor DT are located in the first metal layer M1. The array circuit layer 20 further includes a third pole plate 130 located in the second metal layer M2. An orthographic projection of the third pole plate 130 on the substrate 10 at least partially overlaps with an orthographic projection of the gate 220 of the drive transistor DT on the substrate 10, and the third pole plate 130 and the gate 220 of the drive transistor DT are two pole plates of a second capacitor Cst2.

In an example, the third pole plate 130 receives the fixed voltage. For example, the third pole plate 130 is electrically connected to the first power supply line ELVDD, to transmit the power supply voltage to the third pole plate 130 through the first power supply line ELVDD as the fixed voltage input to the third pole plate 130. The third pole plate 130 and the gate 220 of the drive transistor DT may form the second capacitor Cst2, to store the gate voltage of the drive transistor DT by using the second capacitor Cst2. The first power supply line ELVDD receives the first power supply voltage, and the second power supply line ELVSS receives the second power supply voltage. That is, the second pole plate 120 is in contact with the second electrode 60 to receive the second power supply voltage. The first power supply voltage is different from the second power supply voltage. For example, a voltage value of the first power supply voltage is a positive number, and a voltage value of the second power supply voltage is a negative number or 0. In the technical solutions of the embodiments of the present application, on the basis of implementing the foregoing effects, the first capacitor Cst1 and the second capacitor Cst2 are jointly used as storage capacitors of the pixel circuit. In this way, a total capacitance value of the storage capacitor of the pixel circuit is a sum of the capacitance value of the first capacitor Cst1 and a capacitance value of the second capacitor Cst2. Even in the high PPI design, the capacitance value of the storage capacitor can be increased, to further improve the stability of the gate voltage of the drive transistor DT, and further improve the display effect of the display panel.

Still referring to FIG. 4, the array circuit layer 20 further includes an active layer 210, a third metal layer M3 and a fourth metal layer M4. The active layer 210, the first metal layer M1, the second metal layer M2, the third metal layer M3 and the fourth metal layer M4 are disposed in a stacked manner and are disposed on a side of the substrate 10 in sequence. The source 230 of the drive transistor DT, the drain 240 of the drive transistor DT, and the connection electrode 250 may be disposed in the third metal layer M3, and the connection portion 260 may be disposed in the fourth metal layer M4. In one or more embodiments, the display panel further includes a first encapsulation layer 810, a second encapsulation layer 820 and a third encapsulation layer 830. The first encapsulation layer 810 is formed on a side of the second electrode 60 and the isolation portion 70 facing away from the substrate 10. The first encapsulation layer 810 covers the second electrode 60 and at least part of the isolation portion 70. The second encapsulation layer 820 is formed on a side of the first encapsulation layer 810 and the isolation portion 70 facing away from the substrate 10, and the second encapsulation layer 820 covers the first encapsulation layer 810 and the isolation portion 70. The third encapsulation layer 830 is formed on a side of the second encapsulation layer 820 facing away from the substrate 10, and the third encapsulation layer 830 covers the second encapsulation layer 820.

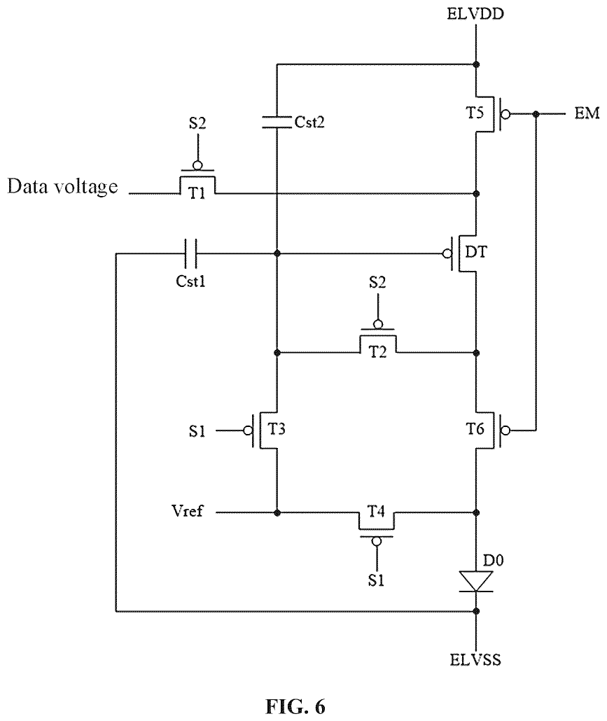

FIG. 6 is another schematic structural diagram of a pixel circuit according to an embodiment of the present application. Referring to FIG. 6, the pixel circuit includes a first transistor T1, a second transistor T2, a third transistor T3, a fourth transistor T4, a fifth transistor T5, a sixth transistor T6 and a drive transistor DT. The pixel circuit further includes the first capacitor Cst1 and the second capacitor Cst2 in any of the above-described embodiments. In an example, the working stage of the pixel circuit includes an initialization stage, a data write stage and a light emitting stage. In the initialization stage, the third transistor T3 and the fourth transistor T4 may be controlled to be turned on in response to the first scan signal S1; the third transistor T3 may be controlled to transmit an initialization voltage input by the initialization signal line Vref to the gate of the drive transistor DT, to initialize the gate voltage of the drive transistor DT; the drive transistor DT may be controlled to be turned on; and the fourth transistor T4 may be controlled to transmit the initialization voltage input by the initialization signal line Vref to the anode of the light emitting device D0, to initialize the anode voltage of the light emitting device D0. In the data write stage, the first transistor T1 and the second transistor T2 may be controlled to be turned on in response to the second scan signal S2, to enable the data voltage input by the data line Data may be transmitted to the gate of the drive transistor DT sequentially through the first transistor T1, the drive transistor DT and the second transistor T2, which enables the gate voltage of the drive transistor DT to be related to both the data voltage and the threshold voltage of the drive transistor DT. The threshold voltage compensation is implemented while the data voltage is written to the drive transistor DT, and the gate voltage of the drive transistor DT is stored by the first capacitor Cst1 and the second capacitor Cst2. In the light emitting stage, the fifth transistor T5 and the sixth transistor T6 may be controlled to be turned on in response to the light emitting control signal EM; and the first transistor T1, the second transistor T2, the third transistor T3 and the fourth transistor T4 may be controlled to be turned off, so that a conductive path is formed between the first power supply line ELVDD and the second power supply line ELVSS. The drive transistor DT may generate the drive current according to the voltage stored in the first capacitor Cst1 and the second capacitor Cst2, to drive the light emitting device D0 to emit light.

In the technical solutions of the embodiments of the present application, the first capacitor Cst1 and the second capacitor Cst2 are jointly used as the storage capacitor of the pixel circuit, so that the capacitance value of the storage capacitor can be increased, constraining the capacitance value of the storage capacitor due to the high PPI design can be avoided, the stability of the gate voltage of the drive transistor DT can be improved, and the display effect of the display panel can be improved.

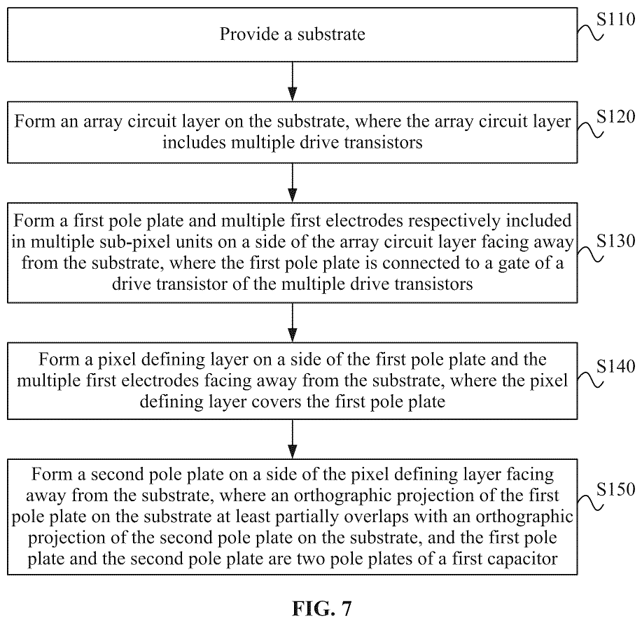

An embodiment of the present application further provides a manufacturing method of a display panel, and the manufacturing method is used for manufacturing the display panel in any of the above-described embodiments. FIG. 7 is a flowchart of a manufacturing method of a display panel according to an embodiment of the present application. Referring to FIG. 7, the manufacturing method includes the following steps.

In S110, a substrate is provided.

In S120, an array circuit layer is formed on the substrate, where the array circuit layer includes multiple drive transistors.

In S130, a first pole plate and multiple first electrodes respectively included in multiple sub-pixel units are formed on a side of the array circuit layer facing away from the substrate, where the first pole plate is connected to a gate of a drive transistor of the multiple drive transistors.

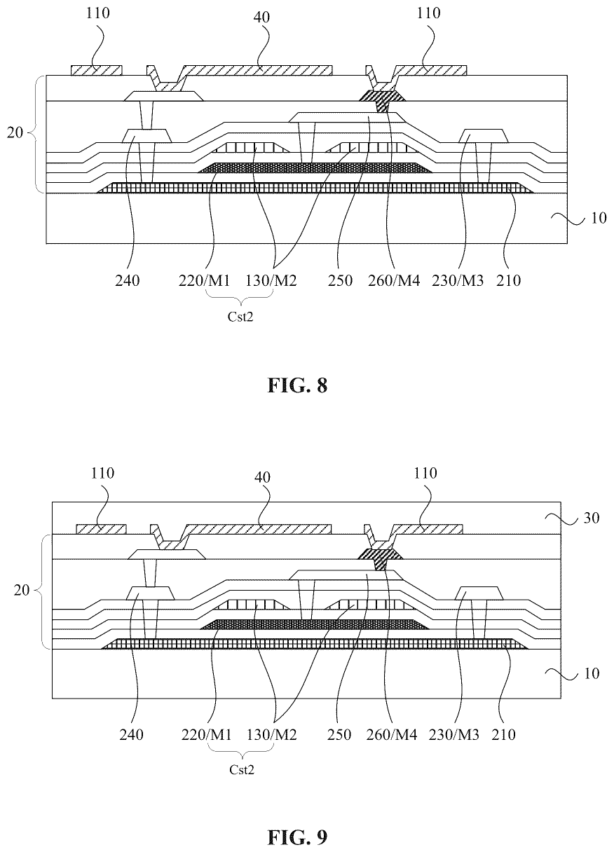

FIG. 8 to FIG. 11 are schematic structural diagrams of display panels formed in part of steps of the manufacturing method of a display panel according to an embodiment of the present application. Referring to FIG. 8, a substrate 10 is provided, an array circuit layer 20 is formed on the substrate 10, multiple pixel circuits are formed in the array circuit layer 20, and each pixel circuit includes a drive transistor DT. In an example, the array circuit layer 20 includes an active layer 210, a first metal layer M1, a second metal layer M2, a third metal layer M3, and a fourth metal layer M4. A gate 220 of the drive transistor DT is located in the first metal layer M1, and a source 230 of the drive transistor DT and a drain 240 of the drive transistor DT are located in the third metal layer M3.

After the array circuit layer 20 is formed, a first electrode 40 and a first pole plate 110 are formed on a side of the array circuit layer 20 facing away from the substrate 10. For example, the first electrode 40 and the first pole plate 110 may be disposed on a side of the fourth metal layer M4 facing away from the substrate 10, and the first pole plate 110 may be connected to the gate 220 of the drive transistor through a connection portion 260 in the fourth metal layer M4 and a connection electrode 250 in the third metal layer M3.

In S140, a pixel defining layer is formed on a side of the first pole plate and the multiple first electrodes facing away from the substrate, where the pixel defining layer covers the first pole plate.

In S150, a second pole plate is formed on a side of the pixel defining layer facing away from the substrate, where an orthographic projection of the first pole plate on the substrate at least partially overlaps with an orthographic projection of the second pole plate on the substrate, and the first pole plate and the second pole plate are two pole plates of a first capacitor.

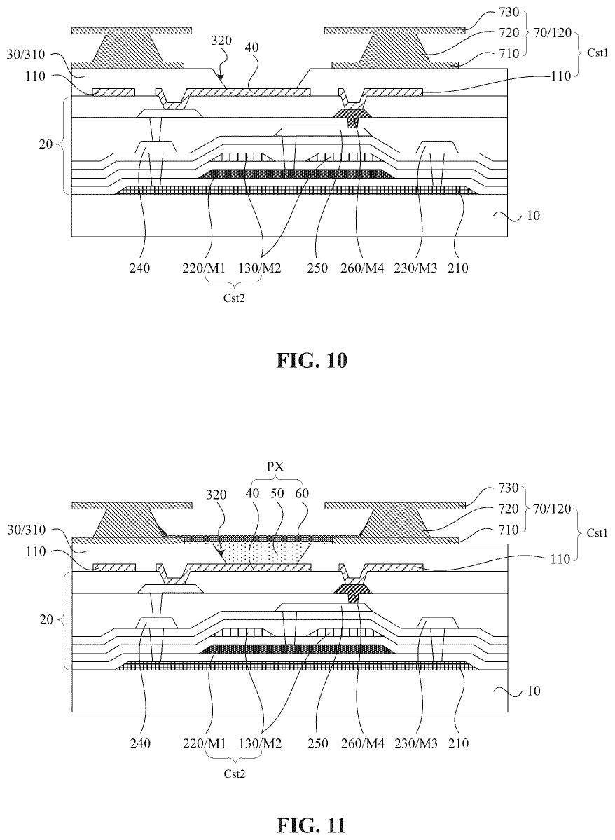

Referring to FIG. 9, a pixel defining layer 30 is formed on a side of the first electrode 40 and the first pole plate 110 facing away from the substrate 10. Referring to FIG. 10, a second pole plate 120 is formed on a side of the pixel defining layer 30 facing away from the substrate 10, so that an orthographic projection of the first pole plate 110 on the substrate 10 at least partially overlaps with an orthographic projection of the second pole plate 120 on the substrate 10, and the first pole plate 110 and the second pole plate 120 form two plates of the first capacitor Cst1.

In the technical solutions of the embodiments of the present application, the first capacitor is formed on the premise of not additionally increasing the display panel film layer and the corresponding mask plate, and the first capacitor is used as the storage capacitor in the pixel circuit, which is conductive to increasing the capacitance value of the storage capacitor, avoiding the high pixels per inch (PPI) design from constraining the capacitance value of the storage capacitor, improving the stability of the gate voltage of the drive transistor by means of increasing the capacitance value of the storage capacitor, and thus improving the display effect of the display panel.

Referring to FIG. 10, in one or more embodiments, the step S150 includes that: an isolation portion 70 is formed on the side of the pixel defining layer 30 facing away from the substrate 10, so that an orthographic projection of the isolation portion 70 on the substrate 10 at least partially overlaps with the orthographic projection of the first pole plate 110 on the substrate 10, and at least part of the isolation portion 70 is also served as the second pole plate 120.

In one or more embodiments, after the step S150, the manufacturing method further includes: an opening region 320 exposing the first pole plate 110 is formed in the pixel defining layer 30, so that the pixel defining layer 30 is formed by pixel defining portions 310 and an opening region 320 formed by enclosing the pixel defining portions 310, and the pixel defining portion 310 covers the first pole plate 110. In an example, after the isolation portion 70 is formed, the opening region 320 of the pixel defining layer 30 may be formed between regions enclosed by the isolation portion 70, so that the isolation portion 70 is disposed around the opening region 320. In other implementation manners, the opening region 320 of the pixel defining layer 30 may be formed firstly, and then the step S150 is performed. For example, the isolation portion 70 is formed, so that the isolation portion 70 is located on the side of the pixel defining portion 310 facing away from the substrate 10, and the isolation portion 70 is disposed around the opening region 320.

Referring to FIG. 11, the manufacturing method further includes S160, in which a light emitting layer 50 of the sub-pixel unit PX is formed in the opening region 320, so that the light emitting layer 50 is located on a side of the first electrode 40 facing away from the substrate 10, is isolated from the light emitting layer 50 of the adjacent sub-pixel units PX by the isolation portion 70, and then a second electrode 60 is formed on a side of the light emitting layer 50 facing away from the substrate 10, so that the second electrode 60 of the adjacent sub-pixel units PX is spaced apart by the isolation portion 70. The first electrode 40, the light emitting layer 50, and the second electrode 60 of the same sub-pixel unit PX are located in the same opening region 320, and the light emitting layer 50 and the second electrode 60 of different sub-pixel units PX are isolated by the isolation portion 70, so that each sub-pixel unit PX is separately controlled. In the process of the manufacturing method of the display panel, the mask is not required to be additionally utilized to isolate different sub-pixel units PX, which is conductive to reducing the manufacturing cost of the display panel. Referring to FIG. 4, after the second electrode 60 is formed, a first encapsulation layer 810 may also be formed on a side of the second electrode 60 and the isolation portion 70 facing away from the substrate 10, so that the first encapsulation layer 810 covers the second electrode 60 and at least part of the isolation portion 70. Then the second encapsulation layer 820 is formed on a side of the first encapsulation layer 810 and the isolation portion 70 facing away from the substrate 10, so that the second encapsulation layer 820 covers the first encapsulation layer 810 and the isolation portion 70. A third encapsulation layer 830 is formed on a side of the second encapsulation layer 820 facing away from the substrate 10, so that the third encapsulation layer 830 covers the second encapsulation layer 820, the encapsulation process of the display panel is completed to obtain the display panel shown in FIG. 4.

An embodiment of the present application further provides a display device. The display device includes the display panel in any of the above-described embodiments, and thus has the corresponding function structure and effect of the display panel, and details are not described herein again. The display device may be a mobile phone, or may be any electronic product that has the display function, and includes but is not limited to the following categories: a television, a notebook computer, a desktop display, a tablet computer, a digital camera, a smart band, smart glasses, an in-vehicle display, a medical apparatus, an industrial control apparatus, a touch interaction terminal and the like, which is not limited in the embodiments of the present application.

What is claimed is:

1. A display panel, comprising:
a substrate;
an array circuit layer located on the substrate and comprising a plurality of drive transistors;
a pixel defining layer and a plurality of sub-pixel units, wherein the pixel defining layer and the plurality of sub-pixel units are located on a side of the array circuit layer facing away from the substrate, and each of the plurality of sub-pixel units comprises a first electrode; and
a first capacitor comprising a first pole plate and a second pole plate, wherein the first pole plate is disposed on a same layer as the first electrode, the pixel defining layer covers the first pole plate, the second pole plate is located on a side of the pixel defining layer facing away from the substrate, an orthographic projection of the first pole plate on the substrate at least partially overlaps with an orthographic projection of the second pole plate on the substrate, and the first pole plate is connected to a gate of a drive transistor of the plurality of drive transistors.

2. The display panel of claim 1, wherein the sub-pixel unit further comprises a second electrode, the second electrode is located on a side of the pixel defining layer facing away from the substrate, and a material of the second pole plate is different from a material of the second electrode.

3. The display panel of claim 1, wherein the second pole plate is disposed on a different layer from the second electrode.

4. The display panel of claim 1, further comprising an isolation portion, wherein the isolation portion is located on a side of the pixel defining layer facing away from the substrate, an orthographic projection of the isolation portion on the substrate at least partially overlaps with the orthographic projection of the first pole plate on the substrate, and at least part of the isolation portion is also served as the second pole plate.

5. The display panel of claim 4, wherein the sub-pixel unit further comprises a light emitting layer and a second electrode that are disposed in a stacked manner and are disposed on a side of the first electrode facing away from the substrate, a gap exists between the light emitting layer of the sub-pixel unit and a side surface of the isolation portion, and the second electrode is lapped to the isolation portion.

6. The display panel of claim 4, wherein the isolation portion comprises a first sub-isolation portion, a second sub-isolation portion, and a third sub-isolation portion that are disposed in a stacked manner and are disposed on the side of the pixel defining layer facing away from the substrate in sequence; and
each of the first sub-isolation, the second sub-isolation, and the third sub-isolation is a conductive isolation, or each of at least two adjacent of the first sub-isolation portion, the second sub-isolation portion, and the third sub-isolation portion is a conductive isolation portion, an orthographic projection of the conductive isolation portion on the substrate at least partially overlaps with the orthographic projection of the first pole plate on the substrate, and at least part of the conductive isolation portion is also served as the second pole plate and is configured to receive a power supply voltage.

7. The display panel of claim 6, wherein in a direction perpendicular to the substrate, a cross-section of the second sub-isolation portion is rectangular or trapezoid, and
wherein when the cross-section of the second sub-isolation portion is trapezoid, a base of the trapezoid is adjacent to the first sub-isolation portion, a top of the trapezoid is adjacent to the third sub-isolation portion, an orthographic projection of the third sub-isolation portion on the substrate covers an orthographic projection of the first sub-isolation portion on the substrate, and the orthographic projection of the third sub-isolation portion on the substrate covers an orthographic projection of the second sub-isolation portion on the substrate.

8. The display panel of claim 1, wherein the pixel defining layer comprises a plurality of pixel defining portions and an opening region formed by enclosing the plurality of pixel defining portions, and the first electrode is exposed outside the opening region; and
a pixel defining portion of the plurality of pixel defining portions covers the first pole plate, the second pole plate is located on a side of the pixel defining portion facing away from the substrate, and the pixel defining portion spaces the first pole plate apart from the second pole plate, wherein the first pole plate is insulated from the second pole plate.

9. The display panel of claim 8, wherein the pixel defining portion comprises at least one of a silicon oxide layer or a silicon nitride layer.

10. The display panel of claim 8, wherein a thickness of the pixel defining portion ranges from 100 nm to 1000 nm in a direction perpendicular to the substrate.

11. The display panel of claim 8, wherein the sub-pixel unit further comprises:
a light emitting layer, wherein the light emitting layer is disposed in the opening region and located on a side of the first electrode facing away from the substrate; and
a second electrode, wherein the second electrode is located on a side of the light emitting layer facing away from the substrate, the second electrode is configured to receive a power supply voltage, and the second electrode is in contact with the second pole plate.

12. The display panel of claim 8, wherein the first pole plate is insulated from the first electrode, and part of the first pole plate is located between adjacent first electrodes;
the first pole plate is disposed around the first electrode; and
the second pole plate is disposed around the opening region of the pixel defining layer, and an overlapping region between the orthographic projection of the first pole plate on the substrate and the orthographic projection of the second pole plate on the substrate surrounds the opening region.

13. The display panel of claim 1, further comprising a connection electrode, wherein the connection electrode is disposed in a same layer as a source of the drive transistor or a drain of the drive transistor, the connection electrode is electrically connected to the gate of the drive transistor and the first pole plate, separately, and an orthographic projection of the connection electrode on the substrate at least partially overlaps with an orthographic projection of the gate of the drive transistor on the substrate.

14. The display panel of claim 1, wherein the array circuit layer further comprises a plurality of metal layers and a third pole plate;
an insulating layer is disposed between two adjacent metal layers among the plurality of metal layers, the plurality of metal layers comprise a first metal layer and a second metal layer, and the gate of the drive transistor is located in the first metal layer; and
the third pole plate is located in the second metal layer, an orthographic projection of the third pole plate on the substrate at least partially overlaps with an orthographic projection of the gate of the drive transistor on the substrate, and the third pole plate and the gate of the drive transistor are two pole plates of a second capacitor.

15. A display panel, comprising:
a substrate;
an array circuit layer located on the substrate and comprising a plurality of drive transistors;
a pixel defining layer and a plurality of sub-pixel units, wherein the pixel defining layer and the plurality of sub-pixel units are located on a side of the array circuit layer facing away from the substrate, each of the plurality of sub-pixel units comprises a first electrode, the pixel defining layer comprises a plurality of pixel defining portions and an opening region formed by enclosing the plurality of pixel defining portions, and the first electrode is exposed outside the opening region;
a first capacitor comprising a first pole plate and a second pole plate, wherein an orthographic projection of the first pole plate on the substrate at least partially overlaps with an orthographic projection of the second pole plate on the substrate, and the first pole plate is connected to a gate of a drive transistor of the plurality of drive transistors; and
an isolation portion located on a side of the substrate, wherein the isolation portion is disposed at least partially around the opening region, an orthographic projection of the isolation portion on the substrate at least partially overlaps with the orthographic projection of the first pole plate on the substrate, and at least part of the isolation portion is also served as the second pole plate.

16. The display panel of claim 15, wherein the first pole plate is disposed on a same layer as the first electrode, the pixel defining layer covers the first pole plate, the isolation portion is located on a side of the pixel defining portions facing away from the substrate, and the isolation portion also serving as the second pole plate is configured to receive a power supply voltage.

17. The display panel of claim 15, wherein the sub-pixel unit further comprises a light emitting layer and a second electrode that are disposed in a stacked manner and are disposed on a side of the first electrode facing away from the substrate, a gap exists between the light emitting layer of the sub-pixel unit and a side surface of the isolation portion, and the second electrode is lapped to the isolation portion.

18. The display panel of claim 15, wherein the isolation portion comprises a first sub-isolation portion, a second sub-isolation portion, and a third sub-isolation portion that are disposed in a stacked manner and are disposed on a side of the pixel defining layer facing away from the substrate in sequence;
each of the first sub-isolation, the second sub-isolation, and the third sub-isolation is a conductive isolation, or each of at least two adjacent of the first sub-isolation portion, the second sub-isolation portion, and the third sub-isolation portion is a conductive isolation portion, an orthographic projection of the conductive isolation portion on the substrate at least partially overlaps with the orthographic projection of the first pole plate on the substrate, and at least part of the conductive isolation portion is configured to receive a power supply voltage and is also served as the second pole plate; and
in a direction perpendicular to the substrate, a length of the third sub-isolation portion is greater than or equal to a length of the first sub-isolation portion, a cross-section of the second sub-isolation portion is rectangular or trapezoid, when the cross-section of the second sub-isolation portion is trapezoid, a base of the trapezoid is adjacent to the first sub-isolation portion, and a top of the trapezoid is adjacent to the third sub-isolation portion.

19. The display panel of claim 15, wherein the array circuit layer further comprises a plurality of metal layers and a third pole plate;
an insulating layer is disposed between two adjacent metal layers among the plurality of metal layers, the plurality of metal layers comprise a first metal layer and a second metal layer, and the gate of the drive transistor is located in the first metal layer; and
the third pole plate is located in the second metal layer, an orthographic projection of the third pole plate on the substrate at least partially overlaps with an orthographic projection of the gate of the drive transistor on the substrate, and the third pole plate and the gate of the drive transistor are two pole plates of a second capacitor.

20. A display device, comprising a display panel,
wherein the display panel comprises:
a substrate;
an array circuit layer located on the substrate and comprising a plurality of drive transistors;
a pixel defining layer and a plurality of sub-pixel units, wherein the pixel defining layer and the plurality of sub-pixel units are located on a side of the array circuit layer facing away from the substrate, and each of the plurality of sub-pixel units comprises a first electrode; and
a first capacitor comprising a first pole plate and a second pole plate, wherein the first pole plate is disposed on a same layer as the first electrode, the pixel defining layer covers the first pole plate, the second pole plate is located on a side of the pixel defining layer facing away from the substrate, an orthographic projection of the first pole plate on the substrate at least partially overlaps with an orthographic projection of the second pole plate on the substrate, and the first pole plate is connected to a gate of a drive transistor of the plurality of drive transistors;
or,
wherein the display panel comprises:
a substrate;
an array circuit layer located on the substrate and comprising a plurality of drive transistors;
a pixel defining layer and a plurality of sub-pixel units, wherein the pixel defining layer and the plurality of sub-pixel units are located on a side of the array circuit layer facing away from the substrate, each of the plurality of sub-pixel units comprises a first electrode, the pixel defining layer comprises a plurality of pixel defining portions and an opening region formed by enclosing the plurality of pixel defining portions, and the first electrode is exposed outside the opening region;
a first capacitor comprising a first pole plate and a second pole plate, wherein an orthographic projection of the first pole plate on the substrate at least partially overlaps with an orthographic projection of the second pole plate on the substrate, and the first pole plate is connected to a gate of a drive transistor of the plurality of drive transistors; and
an isolation portion located on a side of the substrate, wherein the isolation portion is disposed at least partially around the opening region, an orthographic projection of the isolation portion on the substrate at least partially overlaps with the orthographic projection of the first pole plate on the substrate, and at least part of the isolation portion is also served as the second pole plate.
